(19) United States
(12) Patent Application Publication
(10) Pub. No.: US 2014/0264626 A1
(43) Pub. Date: Sep. 18, 2014

(54) METHOD FOR FORMING A GATE ELECTRODE OF A SEMICONDUCTOR DEVICE, GATE ELECTRODE STRUCTURE FOR A SEMICONDUCTOR DEVICE AND ACCORDING SEMICONDUCTOR DEVICE STRUCTURE

(71) Applicant: GLOBALFOUNDRIES Inc., Grand Cayman (KY)

(72) Inventors: Ran Yan, Dresden (DE); Alban Zaka, Dresden (DE); Nicolas Sassiat, Dresden (DE); Jan Hoentschel, Dresden (DE); Martin Trentzsch, Radebeul (DE); Carsten Grass, Dresden (DE)

(73) Assignee: GLOBALFOUNDRIES Inc., Grand Cayman (KY)

(21) Appl. No.: 14/174,474

(22) Filed: Feb. 6, 2014

(30) Foreign Application Priority Data
Mar. 15, 2013 (DE) 10 2013 204 614.6

(51) Int. Cl. H01L 21/8234; H01L 27/088; H01L 29/423

(52) U.S. Cl. CPC H01L 21/823462; H01L 29/42364; H01L 27/088
USPC 257/392; 438/591; 257/411

(57) ABSTRACT

The present disclosure provides, in some aspects, a gate electrode structure for a semiconductor device. In some illustrative embodiments herein, the gate electrode structure includes a first high-k dielectric layer over a first active region of a semiconductor substrate and a second high-k dielectric layer on the first high-k dielectric layer. The first high-k dielectric layer has a metal species incorporated therein for adjusting the work function of the first high-k dielectric layer.

### BACKGROUND OF THE INVENTION

1. Field of the Invention

The present disclosure generally relates to the fabrication of highly sophisticated integrated circuits including advanced transistor elements that comprise gate electrode structures with a high-k gate dielectric, and, more particularly, to methods for forming a gate electrode of a semiconductor device, a gate electrode structure for a semiconductor device and a semiconductor device structure.

2. Description of the Related Art

The majority of present-day integrated circuits (ICs) are implemented by using a plurality of interconnected field effect transistors (FETS), also called metal oxide semiconductor field effect transistors (MOSFETS) or simply MOS transistors. Typically, present-day integrated circuits are implemented by millions of MOS transistors which are formed on a chip having a given surface area.

In MOS transistors, a current flow through a channel formed between a source and a drain of a MOS transistor is controlled via a gate which is typically disposed over the channel region, independent from whether a PMOS transistor or an NMOS transistor is considered. For controlling a MOS transistor, a voltage is applied to the gate electrode of the gate and, when the applied voltage is greater than a threshold voltage, a current flow through the channel is induced. The threshold voltage depends on properties of a transistor, such as size, material, etc., in a nontrivial fashion.

In efforts to build integrated circuits with a greater number of transistors and faster semiconductor devices, developments in semiconductor technologies have aimed at ultra large scale integration (ULSI) which resulted in ICs of ever-decreasing size and, therefore, of MOS transistors having reduced sizes. In present-day semiconductor technology, the minimum feature sizes of microelectronic devices have been approaching the deep sub-micron regime so as to continually meet the demand for faster and lower power microprocessors and digital circuits and generally for semiconductor device structures having improved high energy efficiency. In general, a critical dimension (CD) is represented by a width or length dimension of a line or space that has been identified as critical to the device under fabrication for operating properly and, furthermore, which dimension determines the device performance.

As a result, the continued increase in performance of ICs and the ongoing reduction of IC dimensions to smaller scales has increased the integration density of IC structures. However, as semiconductor devices and device features have become smaller and more advanced, conventional fabrication techniques have been pushed to their limits, challenging their abilities to produce finely defined features at the presently required scales. Consequently, developers are faced with more and more scaling limitations which arise as semiconductors continue to decrease in size.

Normally, IC structures provided on a microchip are realized by millions of individual semiconductor devices, such as PMOS transistors or NMOS transistors. As transistor performance depends crucially on several factors, for example, on the threshold voltage, it is easy to see that it is highly nontrivial to control a chip's performance, which requires keeping many parameters of individual transistors under control, especially for strongly-scaled semiconductor devices. For example, deviations in the threshold voltage of transistor structures across a semiconductor chip strongly affect the reliability of the whole chip under fabrication. In order to ascertain a reliable controllability of transistor devices across a chip, a well-defined adjustment of the threshold voltage for each transistor has to be maintained to a high degree of accuracy. As the threshold voltage alone already depends on many factors, it is necessary to provide a controlled process flow for fabricating transistor devices which reliably meet all these factors.

As is well known, the work function of the gate dielectric material may significantly affect the finally-obtained threshold voltage of field effect transistors, as presently accomplished by appropriately doping the gate material. Upon introducing a high-k dielectric material, the adjustment of an appropriate work function may require the incorporation of appropriate metal species into the gate dielectric material, for instance in the form of lanthanum, aluminum and the like, in order to obtain appropriate work functions and thus threshold voltages for P-channel transistors and N-channel transistors. Moreover, the sensitive high-k dielectric material may have to be protected during processing, while a contact with well-established materials, such as silicon and the like, may also be considered disadvantageous since the Fermi level may be significantly affected upon contacting a high-k dielectric material, such as hafnium oxide, with a gate material. Therefore, a metal-containing cap material is typically provided on the high-k dielectric material to protect the high-k dielectric material during so-called gate-first processes in which the high-k dielectric material is provided in an early manufacturing stage. With the metal-containing material being known to provide superior conductivity characteristics and to avoid any depletion zone, as can be observed in, for instance, polysilicon gate electrode structures, a plurality of additional process steps and material systems are introduced into well-established process techniques, such as CMOS processes, in order to form gate electrode structures having a high-k dielectric material in combination with a metal-containing electrode material. In other approaches, such as replacement gate approaches, gate electrode structures may be provided as placeholder material systems, so-called replacement gates, wherein, after finishing the basic transistor configurations, the replacement gates may be replaced by at least an appropriate metal-containing electrode material, possibly in combination with a high-k dielectric material. Generally, these so-called replacement gate approaches, or gate-last approaches, require complex process sequences for removing the initial replacement gate, such as polysilicon, and forming appropriate metal species for adjusting appropriate work function values by incorporating corresponding work function adjusting species.

It is easy to see that the quality of the gate oxide represents one of the most important issues in any of the current process techniques involving high-k metal gate structures. Current high-k metal gate approaches are requested to exactly and reliably, i.e., reproducibly, incorporate work function tuning elements into the high-k gate material. In general, developers are faced with two major problems when conducting processes for exactly adjusting work function characteristics of high-k materials in current complex integrated circuits. When considering thick high-k material layers, in order to decrease or avoid gate leakage, it turned out that the work function of thick high-k material layers cannot be reliably well adjusted and huge variations of the threshold voltage arise due to changes in the work function from varying amounts of work function tuning elements across the high-k material layers. According to present understanding, not enough work function tuning elements can reach the interface of the high-k material layer towards lower layers formed below the high-k material layer. On the other hand, thin high-k material layers may allow for enough work function tuning elements to reach the interface of the high-k material layer, and therefore significantly reducing variations of the threshold voltage across the integrated circuit elements. However, thin high-k material layers permit a very high gate leakage such that according integrated circuits do not sufficiently satisfy current requirements on power consumption of semiconductor devices to be fabricated.

Prior art document U.S. Pat. No. 8,349,695 teaches adjusting the work function of transistor elements by providing a work function adjusting species within a high-k dielectric material of substantially the same spatial distribution in gate dielectric materials of different thicknesses across various integrated circuits on a given wafer. After having incorporated the work function adjusting species into the high-k dielectric material, the final thickness of the gate dielectric materials is adjusted by selectively forming an additional SiO₂-based dielectric layer. However, a working function adjusting method which avoids the above-described problems of the state of the art, i.e., of huge variations of the threshold voltage arising in current high-k dielectric layers with work function adjusted species incorporated therein, is not solved, as work function tuning species are not reliably and sufficiently exactly incorporated at the interface of the high-k material layer.

Therefore, it is desirable to provide improved work function adjusting processes when forming gate electrode structures of complex semiconductor devices and providing improved gate electrode structures and semiconductor device structures.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

In one aspect of the present disclosure, a method for forming a gate electrode of a semiconductor device is provided. In accordance with illustrative embodiments herein, a method for forming a gate electrode of a semiconductor device includes forming a first high-k dielectric layer over a first active region of a semiconductor substrate, forming a first metal-containing material on the first high-k dielectric layer, performing a first annealing process, removing the first metal-containing material for exposing the first high-k dielectric layer, and forming a second high-k dielectric layer on the first dielectric layer after performing the first annealing process.

In accordance with another aspect of the present disclosure, a gate electrode structure for a semiconductor device is provided, the gate electrode structure including a first high-k dielectric layer over a first active region of a semiconductor substrate and a second high-k dielectric layer on the first dielectric layer, wherein the first high-k dielectric layer has a metal species incorporated therein for adjusting the work function of the first high-k dielectric layer.

In still another aspect of the present disclosure, a semiconductor device structure is provided including a first active region and a second active region formed in a semiconductor substrate, a first gate electrode structure formed over the first active region and a second gate electrode structure formed over the second active region, wherein the first gate electrode structure comprises a first high-k dielectric layer and a second high-k dielectric layer, the first high-k dielectric layer having a first metal species incorporated therein for adjusting a first work function for the first gate electrode structure, wherein the second gate electrode comprises a third high-k dielectric layer and a fourth high-k dielectric layer, the third high-k dielectric layer having a second metal species incorporated therein for adjusting a second work function for the second gate electrode structure.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1e schematically illustrate, in cross-sectional views, a process for forming a gate electrode of a semiconductor device and a semiconductor device structure in accordance with illustrative embodiments of the present invention;

FIGS. 2a-2h schematically illustrate cross-sectional views of further illustrative embodiments of the present invention; and

FIG. 3 schematically illustrates a relation between values of the threshold voltage and gate oxide thicknesses in accordance with conventional semiconductor device structures in comparison with semiconductor device structures in accordance with the present invention.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

The present disclosure relates to semiconductor device structures and particularly to semiconductor devices such as metal oxide semiconductor devices or MOS devices. The person skilled in the art will appreciate that, although the expression “MOS device” is used, no limitation to a metal-containing gate material and/or to an oxide-containing gate dielectric material is intended. Semiconductor devices of the present disclosure, and particularly MOS devices as illustrated by means of some illustrative embodiments as described herein, concern devices fabricated by using advanced technologies. Semiconductor devices, and particularly MOS devices of the present disclosure, are fabricated by technologies applied to approach technology nodes smaller than 100 nm, for example smaller than 50 nm or smaller than 35 nm. The person skilled in the art will appreciate that the present disclosure suggests semiconductor devices, and particularly MOS devices, comprising gate structures such as gate stacks having a gate electrode material layer and a gate dielectric material layer with a length dimension smaller than 100 nm, for example smaller than 50 nm or smaller than 35 nm. A length dimension may be understood as taken along a direction having a non-vanishing projection along a direction of a current flow between the source and drain when the MOS device is in an ON state, the length dimension being, for example, parallel to the direction of current flow between the source and drain.

The multiple embodiments are disclosed and described having some features in common, for clarity and ease of illustration, description and comprehension thereof, similar and like features are ordinarily described with similar reference numerals as a matter of descriptive convenience. Various different embodiments are described with regard to one or more common figures as a matter of descriptive convenience. It is to be understood that this is not intended to have any other significance or provide any limitation for the present disclosure. Any numeration of embodiments, may it be explicit as 1st embodiment, 2nd embodiment, etc., or implied, is a matter of descriptive convenience and is not intended to provide any other significance or limitation for the present disclosure.

The person skilled in the art understands that MOS transistors may be fabricated as P-channel MOS transistors or PMOS transistors and as N-channel transistors or NMOS transistors, and both may be fabricated with or without mobility enhancing stressor features or strain-inducing features. A circuit designer can mix and match device types, using PMOS and NMOS transistors, stressed and unstressed, to take advantage of the best characteristics of each device type as they best suit the circuit being designed. The person skilled in the art understands that stress and strain may be generally described with regard to the tensile modulus.

Various illustrative embodiments of the invention are described below. In the interest of clarity, not all features of an actual implementation are described in this specification. It will, of course, be appreciated that, in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

In accordance with a first aspect of the present disclosure, a method for forming a gate electrode of a semiconductor device is proposed. In some illustrative embodiments herein, the method includes forming a first high-k dielectric layer over a first active region of a semiconductor substrate, forming a first metal-containing material on the first high-k dielectric layer, performing a first annealing process, removing the first metal-containing material for exposing the first high-k dielectric layer, and forming a second high-k dielectric layer on the first dielectric layer after performing the first annealing process. Herein, an effective and reliable way of tuning the work function of the high-k dielectric layer is provided by saturating the work function tuning elements at the interface, while gate leakage TDDB can be improved by forming the second high-k dielectric layer on the first high-k dielectric layer having work function adjusting species incorporated therein. The person skilled in the art will appreciate that only one process type is repeated such that a method may be easily implemented in current fabrication processes.

In accordance with some special illustrative embodiments herein, the first high-k dielectric layer may be formed with a thickness in a range between 0.5-2 nm and preferably in a range between 0.7 nm (7 Å) and 1.4 nm (14 Å). In this way, a reliable and exact saturation of work function tuning elements at the interface of the first high-k dielectric layer may be achieved.

In accordance with some special illustrative embodiments herein, the second high-k dielectric layer may be formed with a thickness in a range between 0.7-2 nm and preferably in a range between 1 nm (10 Å) and 1.6 nm (16 Å). The person skilled in the art will appreciate that an easy way of improving the gate leakage behavior of gate electrode structures may be obtained.

In accordance with some special illustrative embodiments herein, a third high-k dielectric layer may be further formed over a second active region of the semiconductor substrate. A second metal-containing material may be formed on the third high-k dielectric material and a second annealing process may be performed. The second metal-containing material may be removed for exposing the third high-k dielectric layer and a fourth high-k dielectric layer may be formed on the third high-k dielectric layer after performing the second annealing process.

According to some special illustrative embodiments herein, forming the fourth high-k dielectric layer may include depositing the fourth high-k dielectric layer on the third high-k dielectric layer with a first thickness greater than a desired target thickness of the fourth high-k dielectric layer and, subsequently, performing an etching process for obtaining the fourth high-k dielectric layer having the target thickness. The person skilled in the art will appreciate that a thickness of the fourth high-k dielectric layer may be easily adjusted.

In accordance with some special illustrative embodiments herein, the first thickness may be greater than 2 nm (20 Å) and the target thickness may be in a range between 0.7 nm (7 Å) and 2 nm (20 Å). The person skilled in the art will appreciate that these embodiments may be advantageously provided during the fabrication of various semiconductor device structures, such as in CMOS fabrication techniques or in circuit structures having LVT (low threshold voltage) devices and/or RVT (regular threshold voltage) devices and/or HVT (high threshold voltage) devices and/or SHVT (super high threshold voltage) devices.

In accordance with some special illustrative embodiments herein, the first high-k dielectric layer and the third high-k dielectric layer may be formed contiguously and/or the first and second annealing processes may be performed contiguously and/or removing the first and second metal-containing materials may be performed contiguously. The person skilled in the art will appreciate that a plurality of semiconductor device structures may be easily formed.

In accordance with some special illustrative embodiments herein, the first high-k dielectric layer and the third high-k dielectric layer may be formed from the same material and/or the first and second metal-containing materials may be the same and/or the second and fourth high-k dielectric layers may be formed from the same material. The person skilled in the art will appreciate that according embodiments may be advantageously used in fabrication techniques for forming CMOS structures or circuit structures having LVT (low threshold voltage) devices and/or RVT (regular threshold voltage) devices and/or HVT (high threshold voltage) devices and/or SHVT (super high threshold voltage) devices.

In accordance with some special illustrative embodiments herein, the first high-k dielectric layer and the second high-k dielectric layer may comprise the same dielectric material. The person skilled in the art will appreciate that advantageous properties and electrical characteristics may be provided.

In accordance with a second aspect of the present disclosure, a gate electrode structure for a semiconductor device is provided. In some special illustrative embodiments herein, the gate electrode structure includes a first high-k dielectric layer over a first active region of a semiconductor substrate and a second high-k dielectric layer on the first high-k dielectric layer, wherein the first high-k dielectric layer has a metal species incorporated therein for adjusting the work function of the first high-k dielectric layer. In a special illustrative embodiment herein, the first high-k dielectric layer may have a thickness in a range between 0.5-2 nm and preferably in a range between 0.7-1.4 nm. In some special illustrative embodiments herein, the second high-k dielectric layer may have a thickness in a range between 0.7-2 nm and preferably in a range between 1-1.6 nm. In some special illustrative embodiments herein, the first high-k dielectric layer and the second high-k dielectric layer may have different dielectric materials.

In a third aspect of the present disclosure, a semiconductor device structure is provided. In a special illustrative embodiment, the semiconductor device structure may include a first active region and a second active region formed in a semiconductor substrate, a first gate electrode structure formed over the first active region and a second gate electrode structure formed over the second active region, wherein the first gate electrode structure comprises a first high-k dielectric layer and a second high-k dielectric layer, the first high-k dielectric layer having a first metal species incorporated therein for adjusting a first work function for the first gate electrode structure, wherein the second gate electrode comprises a third high-k dielectric layer and a fourth high-k dielectric layer, the third high-k dielectric layer having a second metal species incorporated therein for adjusting a second work function for the second gate electrode structure.

In some special illustrative embodiments herein, the first high-k dielectric layer and the third high-k dielectric layer may be formed from the same material and/or the first and second metal-containing materials may be the same and/or the second and fourth high-k dielectric layers may be formed from the same material. In some special illustrative embodiments herein, the first high-k dielectric layer and the second high-k dielectric layer may comprise the same dielectric material.

In some special illustrative embodiments herein, a thickness of the first high-k dielectric layer may be smaller than a thickness of the second high-k dielectric layer and/or than a thickness of the third high-k dielectric layer. In some special illustrative embodiments herein, a thickness of the third high-k dielectric layer may be smaller than a thickness of the fourth high-k dielectric layer and/or than a thickness of the second high-k dielectric layer.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

With regard to FIGS. 1a-1e, illustrative embodiments will be schematically described. FIG. 1a schematically illustrates a cross-sectional view of a semiconductor device 100 comprising a substrate 101 and a semiconductor layer 102, such as a silicon-based layer and the like, wherein, if appropriate, a buried insulating layer (not shown) may be formed between the substrate 101 and the semiconductor layer 102. That is, the device 100 may comprise device regions having a bulk configuration or a silicon-on-insulator (SOI) configuration. The semiconductor device 100 may be associated with a corresponding semiconductor region or active region and may be laterally delineated by appropriate isolation structures, as will be described later on in more detail. Moreover, in the manufacturing stage shown, a dielectric base layer 152, such as a silicon oxide-based material or any other appropriate dielectric material, such as silicon oxynitride and the like, may be formed, followed by a high-k dielectric material 153. The dielectric base layer 152 may be formed by oxidation and/or deposition, possibly in combination with other surface treatments and the like, depending on the desired material composition. Similarly, the high-k dielectric material 153, in one illustrative embodiment, may be provided in the form of hafnium oxide and may be deposited on the basis of any appropriate deposition technique.

FIG. 1b schematically illustrates the semiconductor device 100 with a metal-containing cap layer 107 formed on the high-k dielectric material 153, followed by a further metal-containing material 154, wherein, in other illustrative embodiments, the materials 107, 154 may be provided in the form of a single material layer, if considered appropriate. For instance, the layer 107 may be provided in the form of a titanium nitride material with a thickness of several Angstrom to several nanometers or even thicker, while the material layer 154 may be provided with a thickness of several Angstrom to several nanometers, depending on the desired concentration of a work function adjusting species to be formed within the gate dielectric material comprised of the materials 152 and 153. It should be appreciated that FIG. 1b illustrates the material layer stack as may be required for adjusting the work function of a specific transistor type, such as a P-channel transistor or an N-channel transistor, wherein, in other cases, additional material layers may be provided, for instance a further titanium nitride material in combination with an additional work function adjusting species may be provided above the material system as shown in FIG. 1b in order to obtain the desired work function adjustment in other device areas, in which the material system of FIG. 1b may have been removed. In this case, a material system as shown in FIG. 1b may be provided in device areas with an appropriately adapted material layer 154. For convenience, any such configurations for forming material systems for adjusting the work function of transistors of different conductivity type are not shown in FIG. 1b. Consequently, the layer 107 or the layer 154 may comprise an appropriate species, such as lanthanum for N-channel transistors, aluminum and the like, which is to be incorporated in the gate dielectric material comprised of the layers 152 and 153.

FIG. 1c schematically illustrates the semiconductor device 100 during a heat treatment 108 in which the layer 154 or any species contained therein may be diffused into the gate dielectric material, i.e., into the high-k dielectric material 153 and substantially to an interface 153S, depending on the diffusion blocking capability of the dielectric base layer 152. Consequently, during the treatment 108, which may be performed on the basis of appropriate temperatures in the range of approximately 700-1000° C. for instance, fixed charges 154A may be positioned within the materials 153, 152 and preferably at the interface 153S. Consequently, a concentration and a location of the fixed charges 154A may be formed such that very uniform conditions for adjusting the desired work function and hence the threshold voltage of transistor elements are provided in and above the semiconductor device 100.

FIG. 1d schematically illustrates the device 100 in a further advanced manufacturing stage in which a portion of the material layer 107 (FIG. 1c) may be selectively removed from above the high-k dielectric material 153, above which is to be formed a gate electrode structure having a gate dielectric material, particularly a high-k dielectric layer, with reliably adjusted work function at the interface of the high-k dielectric layer. For this purpose, any appropriate etch recipe may be applied in combination with an appropriate etch mask, wherein the high-k dielectric material 153 may act as an etch stop material. Consequently, a portion of the layer 107 may remain, thereby further covering the high-k dielectric material 153.

Furthermore, as shown in FIG. 1d, a dielectric layer 155 may be formed above the high-k material 153 having work function tuning species 154A incorporated therein to form a gate dielectric structure 159 for the semiconductor device 100. The dielectric layer 155 may be provided in the form of a high-k material. According to some illustrative embodiments, the high-k material of the dielectric layer 155 may be the same as the high-k material 153, while, in other cases, any other appropriate high-k dielectric material may be used in order to obtain the desired transistor performance for a gate electrode structure requiring exactly located work function tuning species at the interface of the high-k material 153. The person skilled in the art will appreciate that well-established chemical vapor deposition (CVD) techniques may be applied to form high-k material layers with an appropriate thickness.

FIG. 1e schematically illustrates the device 100 in a further advanced manufacturing stage. As illustrated, a transistor is formed in an active region comprising the semiconductor layer 102 and may comprise drain and source regions 161, which may laterally enclose a channel region 162. Furthermore, the transistor 100 may comprise a gate electrode structure 150 including the gate dielectric structure 159, i.e., the layers 152 and 153, followed by a metal-containing electrode material 155, such as a titanium nitride material and the like, in combination with a further electrode material 156, such as a polysilicon material, a silicon/germanium mixture and the like. Furthermore, a sidewall spacer structure 160 in accordance with process and device requirements may be formed on sidewalls of the electrode materials 156, 155 and the gate dielectric structure 159.

With respect to any manufacturing techniques for forming the transistor 100 as shown in FIG. 1e, any appropriate process strategy may be applied, for instance as previously explained with reference to the semiconductor device 100, wherein, in the embodiment shown, the channel region 162 and the drain and source regions 161 may be formed on the basis of a common process sequence. That is, due to the high degree of uniformity of the spatial distribution of the work function adjusting species within the gate dielectric structure 159, and in particular in the high-k dielectric material 152, as previously explained, a high degree of uniformity of the threshold voltage characteristics may be achieved, while at the same time the desired difference in thickness of the gate dielectric structure 159 may be provided.

The person skilled in the art will appreciate that, in accordance with some illustrative examples of the present invention, the transistor 100 as shown in FIG. 1e may be designed for high performance applications. The gate dielectric structure 159 may then be formed so as to provide an LVT device or an RVT device in dependence on specific applications of the transistor 100.

With reference to FIGS. 2a-2h, further illustrative embodiments will now be described in more detail, wherein reference may also be made to FIGS. 1a-1e, when appropriate.

FIG. 2a schematically illustrates a cross-sectional view of a semiconductor device 200 comprising a substrate 201 and a semiconductor layer 202, such as a silicon-based layer and the like, wherein, if appropriate, a buried insulating layer (not shown) may be formed between the substrate 201 and the semiconductor layer 202, at least in some device regions, such as regions 200A, 200B. That is, the device 200 may comprise device regions having a bulk configuration, a silicon-on-insulator (SOI) configuration or both configurations may be used in different device regions. Corresponding semiconductor regions or active regions 202A, 202B may be provided in the device regions 200A, 200B, respectively, which may be laterally delineated by appropriate isolation structures, as will be described later on in more detail. Moreover, in the manufacturing stage shown, a dielectric base layer 252, such as a silicon oxide-based material or any other appropriate dielectric material, such as silicon oxynitride and the like, may be formed on the active regions 202A, 202B, followed by a high-k dielectric material 253. With respect to a thickness and material composition of the high-k dielectric material 253, the same criteria may apply as previously explained with reference to the semiconductor device 100. The dielectric base layer 252 may be formed by oxidation and/or deposition, possibly in combination with other surface treatments and the like, depending on the desired material composition. Similarly, the high-k dielectric material 253, which, in one illustrative embodiment, may be provided in the form of hafnium oxide, may be deposited on the basis of any appropriate deposition technique.

FIG. 2b schematically illustrates the semiconductor device 200 with a metal-containing cap layer 207 formed on the high-k dielectric material 253, followed by a further metal-containing material 254, wherein, in other illustrative embodiments, the materials 207, 254 may be provided in the form of a single material layer, if considered appropriate. For instance, the layer 207 may be provided in the form of a titanium nitride material with a thickness of several Angstrom to several nanometers or even thicker, while the material layer 254 may be provided with a thickness of several Angstrom to several nanometers, depending on the desired concentration of a work function adjusting species to be formed within the gate dielectric material comprised of the materials 252 and 253. It should be appreciated that FIG. 2b illustrates the material layer stack as may be required for adjusting the work function of a specific transistor type, such as a P-channel transistor or an N-channel transistor, wherein, in other cases, additional material layers may be provided, for instance a further titanium nitride material in combination with an additional work function adjusting species may be provided above the material system as shown in FIG. 2b in order to obtain the desired work function adjustment in other device areas, in which the material system of FIG. 2b may have been removed. In this case, a material system as shown in FIG. 2b may be provided in device areas with an appropriately adapted material layer 254. For convenience, any such configurations for forming material systems for adjusting the work function of transistors of different conductivity type are not shown in FIG. 2b. Consequently, the layer 207 or the layer 254 may comprise an appropriate species, such as lanthanum for N-channel transistors, aluminum and the like, which is to be incorporated in the gate dielectric material comprised of the layers 252 and 253. With respect to any deposition techniques for forming the layers 207 and 254, it may be referred to the semiconductor device 100, as previously described with reference to FIGS. 1a-1e.

FIG. 2c schematically illustrates the semiconductor device 200 during a heat treatment 208 in which the layer 254 or any species contained therein may be diffused into the gate dielectric material, i.e., into the high-k dielectric material 253 and substantially to an interface 253S, depending on the diffusion blocking capability of the dielectric base layer 252. Consequently, during the treatment 208, which may be performed on the basis of appropriate temperatures in the range of approximately 700-1000° C. for instance, fixed charges 254A may be positioned within the materials 253, 252 and preferably at the interface 253S, wherein substantially the same conditions may prevail in the first and second semiconductor regions 200A, 200B. Consequently, a concentration and a location of the fixed charges 254A above the active regions 202A, 202B may be substantially the same, thereby providing very uniform conditions for adjusting the desired work function and hence the threshold voltage of transistor elements to be formed in and above the active regions 202A, 202B, respectively.

FIG. 2d schematically illustrates the device 200 in a further advanced manufacturing stage in which a portion of the material layer 207 (FIG. 2c) may be selectively removed from above the active region 202B, above which is to be formed a gate electrode structure having a gate dielectric material with increased thickness compared to the active region 202A. For this purpose, any appropriate etch recipe may be applied in combination with an appropriate etch mask, wherein the high-k dielectric material 253 may act as an etch stop material above the active region 202B. Consequently, a portion 207A may remain above the active region 202A, thereby further covering the high-k dielectric material 253.

FIG. 2e schematically illustrates the device 200 with a further dielectric layer 251 formed above the active regions 202A, 202B. The dielectric layer 251 is preferably provided in the form of a high-k material. The person skilled in the art will appreciate that the high-k material of the dielectric layer 251 may be substantially similar to the high-k material 253 in some explicit examples. Alternatively, any other appropriate dielectric materials may be used in other cases in order to obtain the desired transistor performance for a gate electrode structure requiring an increased thickness of a gate dielectric material. Hence, the thickness and material composition of the dielectric layer 251 may be selected such that, in combination with the layers 252 and 253, a desired gate dielectric material may be obtained above the active region 202B. For this purpose, well-established CVD techniques may be applied to form materials such as silicon dioxide with an appropriate thickness.

FIG. 2f schematically illustrates the device 200 in a further advanced manufacturing stage in which the dielectric layer 251 (FIG. 2e) is selectively removed from above the active region 202A. For this purpose, an appropriate etch mask, such as a resist mask, may be provided (not shown) and the device 200 may be exposed to an appropriate etch ambient, for instance a wet chemical etch ambient based on hydrofluoric acid (HF) when the material 251 is comprised of silicon dioxide. With other materials, any other appropriate etch chemistry may be applied. During the etch process, the remaining layer 207A may act as an efficient etch stop material, for instance in the form of titanium nitride, which exhibits a high etch selectivity with respect to HF, thereby reliably protecting the underlying high-k material 253. Consequently, a first gate dielectric material 259A may be formed on the active region 202A and may be comprised of the layers 252 and 253 including the work function adjusting species 254A, while a second thicker gate dielectric material 259B may be formed on the active region 202B and may be comprised of the materials 252 and 253 in combination with the dielectric layer 251B. On the other hand, the gate dielectric material 259B may also comprise the work function adjusting species 254A with the same concentration and spatial distribution, except for any process-related non-uniformities, as the gate dielectric material 259A, thereby providing a high degree of uniformity, for instance in terms of threshold voltage of transistors still to be formed.

FIG. 2g schematically illustrates the device 200 in a manufacturing stage in which a metal-containing electrode material or cap material 255 may be formed on the gate dielectric materials 259A, 259B. In one illustrative embodiment, the material 255 may be provided in the form of a titanium nitride material, while, in other cases, any other appropriate material or materials may be provided, depending on the overall required configuration of the gate electrode structures still to be formed. For this purpose, the remaining layer 207A (FIG. 2f) may be removed by any appropriate etch recipe, which may have a pronounced etch selectivity with respect to the high-k dielectric material 253. Hence, any such etch recipe may be advantageously applied so as to efficiently remove the titanium nitride material while substantially not unduly affecting the high-k dielectric material 253 and also maintaining integrity of the dielectric layer 251B. If required, an etch mask may be provided to cover the gate dielectric material 259B.

FIG. 2h schematically illustrates the device 200 in a further advanced manufacturing stage. As illustrated, a first transistor 260A is formed in and above the active region 202A and may comprise drain and source regions 261, which may laterally enclose a channel region 262. Similarly, a second transistor 260B may be formed in and above the active region 202B and may comprise the drain and source regions 261 in combination with the channel region 262, wherein, in some illustrative embodiments, the doping profile of the drain and source regions 261 and of the channel region 262 may be substantially the same for the transistors 260A, 260B. Furthermore, the transistor 260A may comprise a first gate electrode structure 250A including the gate dielectric material 259A, i.e., the layers 252 and 253, followed by the metal-containing electrode material 255, such as a titanium nitride material and the like, in combination with a further electrode material 256, such as a polysilicon material, a silicon/germanium mixture and the like. Similarly, the second transistor 260B may comprise a second gate electrode structure 250B comprising the gate dielectric material 259B having the increased thickness due to the presence of the dielectric layer 251B in combination with the material layers 252 and 253. Furthermore, the metal-containing material 255 may be provided in combination with the electrode material 256. Furthermore, a sidewall spacer structure 257 in accordance with process and device requirements may be formed on sidewalls of the electrode materials 256, 255 and the gate dielectric materials 259A, 259B.

With respect to any manufacturing techniques for forming the transistors 260A, 260B, any appropriate process strategy may be applied, for instance as previously explained with reference to the semiconductor device 100, wherein, in the embodiment shown, the channel regions 262 and the drain and source regions 261 may be formed on the basis of a common process sequence without requiring additional processes for adjusting the finally desired threshold voltage for the transistors 260A, 260B. That is, due to the high degree of uniformity of the spatial distribution of the work function adjusting species within the materials 252 and 253, as previously explained, a high degree of uniformity of the threshold voltage characteristics may be achieved, while at the same time the desired difference in thickness of the gate dielectric materials 259A, 259B may be provided.

The person skilled in the art will appreciate that the illustrative embodiments as described with regard to FIGS. 2a-2h may be advantageously applied in CMOS techniques and/or with regard to the implementation of combinations of LVT, RVT, HVT and SHVT devices. The person skilled in the art will appreciate that a first transistor may be of an LVT or RVT type, while the second transistor may be of an HVT or SHVT type. This does not pose any limitation on the present invention and the person skilled in the art will appreciate that any other combinations may be considered. The person skilled in the art will appreciate that, in HVT and SHVT applications, a further dielectric material may be deposited on a first high-k material layer and/or a second high-k material layer.

The person skilled in the art will appreciate that, although not explicitly described with regard to the various illustrative embodiments provided above, a base oxide layer may be present between the semiconductor substrate and a high-k material layer of some illustrative gate electrodes.

FIG. 3 graphically represents a relation between threshold voltage values and thickness values of the gate oxide in semiconductor device structures. Herein, an axis 315 is related to gate oxide equivalent thickness values (EOT=equivalent oxide thickness; EOT is obtained by the thicknesses of high-k material and base oxide), while an axis 325 relates to threshold voltage values. A relation between threshold voltages and gate oxide thicknesses for conventional semiconductor structures is represented by graph 335, wherein squares denoted by reference numeral 337 represent data values that are typically obtained in current semiconductor devices. For example, due to illustrative examples, the graphical representation 335 may represent data implying that, for example, EOTs of about 2.9 nm show a variation of long channel threshold voltage of about 70 mV/A due to the different amount of work function tuning elements reaching the interface of the high-k dielectric layer with an underlying material layer, such as a base oxide layer. By contrast, a graphical represented relation 345 may illustrate a dependence of the threshold voltage on the gate oxide equivalent thickness or EOT in semiconductor device structures according to illustrative embodiments of the present invention. Herein, circles denoted by reference numeral 347 represent data values obtained in illustrative embodiments of the present disclosure. For example, the inventors have shown that, in illustrative examples of the present invention, a variation in the threshold voltage is almost approximately 0 mV/A at EOTs in the order of 1.9 nm due to the saturation of work function tuning elements at the interface of the high-k dielectric layer. In accordance with some illustrative examples, thickness values of only the first high-k layer thickness may be about 2 nm (curve 335) and about 1 nm (curve 345).

It is noted that, in accordance with some illustrative embodiments of the present invention, the final gate oxide equivalent thickness may be targeted to be between 1.2 nm and 1.7 nm, such that the different high-k layers may vary in between 0.5 nm and 2 nm, which also depends on the k value of the high-k material.

The person skilled in the art will appreciate that the illustration in FIG. 3 is merely a schematic representation and the objects denoted by reference numerals 337 and 347 may actually represent at least one measured data point or a plurality of data points or may even represent median values or averaged data values obtained in experiments.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method for forming a gate electrode of a semiconductor device, the method comprising:
forming a first high-k dielectric layer over a first active region of a semiconductor substrate;
forming a first metal-containing material on said first high-k dielectric layer;
performing a first annealing process;
removing said first metal-containing material for exposing said first high-k dielectric layer; and
forming a second high-k dielectric layer on said first dielectric layer after performing said first annealing process.

2. The method of claim 1, wherein said first high-k dielectric layer is formed with a thickness in a range between 0.5 nm and 2 nm.

3. The method of claim 2, wherein said second high-k dielectric layer is formed with a thickness in a range between 0.7 nm and 2 nm.

4. The method of claim 1, further comprising forming a third high-k dielectric layer over a second active region of said semiconductor substrate, forming a second metal-containing material on said third high-k dielectric layer, performing a second annealing process, removing said second metal-containing material for exposing said third high-k dielectric layer, and forming a fourth high-k dielectric layer on said third high-k dielectric layer after performing said second annealing process.

5. The method of claim 4, wherein forming said fourth high-k dielectric layer comprises depositing said fourth high-k dielectric layer on said third high-k dielectric layer with a first thickness greater than a desired target thickness of said fourth high-k dielectric layer and subsequently performing an etching process for obtaining said fourth high-k dielectric layer having said target thickness.

6. The method of claim 5, wherein said first thickness is greater than 2 nm and said target thickness is in a range between 0.5 nm and 2 nm.

7. The method of claim 6, wherein said first high-k dielectric layer and said third high-k dielectric layer are formed contiguously and/or said first and second annealing processes are performed contiguously and/or said removing of said first and second metal-containing materials is preformed contiguously.

8. The method of claim 6, wherein said first high-k dielectric layer and said third high-k dielectric layer are formed from the same material and/or said first and second metal-containing materials are the same and/or said second and fourth high-k dielectric layers are formed from the same material.

9. The method of claim 1, wherein said first high-k dielectric layer and said second high-k dielectric layer comprise the same dielectric material.

10. A gate electrode structure for a semiconductor device, said gate electrode structure comprising:
a first high-k dielectric layer over a first active region of a semiconductor substrate; and
a second high-k dielectric layer on said first dielectric layer;
wherein said first high-k dielectric layer has a metal species incorporated therein for adjusting the work function of said first high-k dielectric layer.

11. The gate electrode structure of claim 10, wherein said first high-k dielectric layer has a thickness in a range between 0.5 nm and 2 nm.

12. The gate electrode structure of claim 11, wherein said second high-k dielectric layer has a thickness in a range between 0.7 and 2 nm.

13. The gate electrode structure of claim 10, wherein said first high-k dielectric layer and said second high-k dielectric layer have different dielectric materials.

14. A semiconductor device structure, comprising:
a first active region and a second active region formed in a semiconductor substrate; and
a first gate electrode structure formed over said first active region and a second gate electrode structure formed over said second active region;
wherein said first gate electrode structure comprises a first high-k dielectric layer and a second high-k dielectric layer, said first high-k dielectric layer having a first metal species incorporated therein for adjusting a first work function for said first gate electrode structure;
wherein said second gate electrode comprises a third high-k dielectric layer and a fourth high-k dielectric layer, said third high-k dielectric layer having a second metal species incorporated therein for adjusting a second work function for said second gate electrode structure.

15. The semiconductor device structure of claim 14, wherein said first high-k dielectric layer and said third high-k dielectric layer are formed from the same material and/or said first and second metal-containing materials are the same and/or said second and fourth high-k dielectric layers are formed from the same material.

16. The semiconductor device structure of claim 14, wherein said first high-k dielectric layer and said second high-k dielectric layer comprise the same dielectric material.

17. The semiconductor device structure of claim 14, wherein a thickness of said first high-k dielectric layer is smaller than a thickness of said second high-k dielectric layer and/or than a thickness of said third high-k dielectric layer.

18. The semiconductor device structure of claim 14, wherein a thickness of said third high-k dielectric layer is smaller than a thickness of said fourth high-k dielectric layer and/or than a thickness of said second high-k dielectric layer.
